(19) United States
(12) Patent Application Publication
(10) Pub. No.: US 2025/0285843 A1
(43) Pub. Date: Sep. 11, 2025

(54) SYSTEMS AND METHODS FOR HIGH-THROUGHPUT ANGLED ION PROCESSING

(71) Applicant: Applied Materials, Inc., Santa Clara, CA (US)

(72) Inventors: Alexandre LIKHANSKII, Malden, MA (US); Russell Chin Yee TEO, Palo Alto, CA (US); Christopher CAMPBELL, Newburyport, MA (US); Lei JIANG, San Ramon, CA (US); Zefang WANG, Santa Clara, CA (US); Costel BILOIU, Rockport, MA (US)

(73) Assignee: Applied Materials, Inc., Santa Clara, CA (US)

(21) Appl. No.: 18/597,543

(22) Filed: Mar. 6, 2024

(51) Int. Cl. H01J 37/32

(52) U.S. Cl. CPC H01J 37/32623; H01J 2237/0453

(57) ABSTRACT

Disclosed herein are systems and methods for high throughput angled ion processing. In one approach, a processing apparatus may include a chamber operable to contain a plasma, the chamber defined by a plurality of sidewalls, and a plate assembly arranged along a side of the chamber. The plate assembly may include a plate defining a plurality of apertures, wherein ions are extracted through the plurality of apertures and delivered to a substrate at a non-zero angle relative to a perpendicular extending from the substrate. The processing apparatus may further include an actuator operable to dither the moveable plates and the substrate relative to one another as the ions are extracted through the plurality of apertures.

### FIELD OF THE DISCLOSURE

Embodiments of the present disclosure relate to an apparatus and method for extracting an angled ion beam from a plasma chamber and, more particularly, to an apparatus and method for extracting a low-energy, high-current angled ion beam.

### BACKGROUND OF THE DISCLOSURE

Recently, there has been a transition to create three-dimensional devices in the semiconductor industry. To process these three-dimensional devices, angled ion implants are often used. Angled ion implants refer to those ion beams which strike the substrate at a non-zero angle. Angled ion beams have many applications. For example, angled ion beams may be used to implant a sidewall of a fin structure or a trench, or may be used for etching processes, deposition processes, and other applications.

One way to perform these angled ion implants is to rotate or tilt the platen on which the substrate is disposed. In other words, the ion beam is generated in the traditional manner, but the platen is tilted so that the ion beam strikes the substrate at a non-zero angle. This approach may allow the generation of an ion beam which strikes the substrate at an angle of 20° or more. One shortcoming with this approach is that the various regions of the substrate are at different distances from the ion beam source. For example, by tilting, several regions of the substrate will be closer to the ion beam source than other regions. This may cause process variations across the substrate.

Another approach is to rotate the ion beam source with respect to the substrate to achieve the desired angle of the extracted ion beam. This approach has similar shortcomings as the previously described method of tilting the substrate.

Yet another approach is to control and vary the shape of the plasma sheath to vary the angle of the ions extracted from a plasma processing chamber. However, this approach may have limitations in terms of the amount of current that may be extracted.

Therefore, it would be advantageous if there was a system for generating a high-current, low-energy angled ion beam that does not suffer from these limitations. Further, it would be beneficial if the angle used for the ion implant was highly adjustable and easy to manipulate.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a processing apparatus may include a chamber operable to contain a plasma within a chamber volume, the chamber defined by a plurality of sidewalls, and a plate assembly arranged above a substrate. The plate assembly may include a plate defining a plurality of openings, wherein ions are extracted through the plurality of openings and delivered to the substrate at a non-zero angle relative to a perpendicular extending from the substrate. The processing apparatus may further include an actuator operable to dither the plate and the substrate relative to one another as the ions are extracted through the plurality of apertures.

In another aspect, a plasma processing apparatus may include a plasma chamber operable to contain a plasma within a chamber volume, the plasma chamber defined by a plurality of sidewalls, and a plate assembly within the plasma chamber, wherein the plate assembly is arranged above a substrate. The plate assembly may include a plate defining a plurality of apertures, wherein ions are extracted through the plurality of apertures and delivered to the substrate at a non-zero angle relative to a perpendicular extending from the substrate. The plasma processing apparatus may further include an actuator operable to dither the plate and the substrate relative to one another as the ions are extracted through the plurality of apertures.

In yet another aspect, a method may include generating a plasma within a chamber volume of a plasma chamber, wherein the plasma chamber is defined by a plurality of sidewall, and arranging a plate assembly above a substrate, and wherein the plate assembly may include a plate defining a plurality of apertures. The method may further include extracting ions through the plurality of apertures, delivering the ions to the substrate at a non-zero angle relative to a perpendicular extending from a plane defined by a top surface of the substrate, and dithering the plate and the substrate relative to one another as the ions are extracted through the plurality of apertures and delivered to the substrate.

### BRIEF DESCRIPTION OF THE DRAWINGS

The accompanying drawings illustrate exemplary approaches of the disclosure, including the practical application of the principles thereof, as follows:

FIG. 1 is a schematic cross-sectional view of a processing apparatus including an exemplary plasma processing chamber according to one or more embodiments;

FIG. 2 is cross-sectional view of an exemplary plasma processing chamber according to one or more embodiments;

FIG. 3A is a perspective view of a plate and wafer according to one or more embodiments;

FIG. 3B is a perspective view of a portion of the plate of FIG. 3A according to one or more embodiments;

FIG. 4A is a side view of a plate in a first position, according to one or more embodiments;

FIG. 4B is a graph of an ion flux at the wafer when the plate in the first position, according to one or more embodiments;

FIG. 5A is a side view of a plate in a second position, according to one or more embodiments;

FIG. 5B is a graph of the ion flux at the wafer when the plate in the second position, according to one or more embodiments;

FIG. 6A is a side view of a plate in a third position, according to one or more embodiments;

FIG. 6B is a graph of the ion flux at the wafer when the plate in the third position, according to one or more embodiments;

FIG. 7A is a side view of a plate in a fourth position, according to one or more embodiments;

FIG. 7B is a graph of the ion flux at the wafer when the plate in the fourth position, according to one or more embodiments;

FIG. 8A is a side view of a plate in a fifth position, according to one or more embodiments;

FIG. 8B is a graph of the ion flux at the wafer when the plate in the fifth position, according to one or more embodiments;

FIG. 9A is a side view of a plate assembly according to one or more embodiments;

FIG. 9B is a side view of a plurality of plates of another plate assembly according to one or more embodiments;

FIG. 10 is a schematic top plan view of an exemplary cluster processing system according to one or more embodiments; and

FIG. 11 depicts a flow diagram illustrating a process according to one or more embodiments.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, systems, and apparatuses in accordance with the present disclosure will now be described more fully hereinafter with reference to the accompanying drawings, where various embodiments are shown. The methods systems, and apparatuses may be embodied in many different forms and are not to be construed as being limited to the embodiments set forth herein. Instead, these embodiments are provided so the disclosure will be thorough and complete, and will fully convey the scope of the methods to those skilled in the art.

To address the deficiencies of the prior art described above, embodiments of the present disclosure advantageously provide periodic ion extraction optics for conventional plasma etchers to enable improved angled ion capabilities. For example, uniformity of an ion etch process is enabled by optics dithering and adjustable ion extraction duty cycle. A more uniform directional deposition of a material is also possible using the same principles.

Notably, uniformity of ions on the wafer may be maintained, particularly at “turn around points,” which are typically when the wafer is slowing or stopped and thus subject to increased and/or varied ion flux. To compensate, an amount of ions directed through apertures of the optics is reduced during the time when the wafer is at each turnaround point. One way to do this is by adjusting the duty cycle of the bias signal that attracts ions to the wafer.

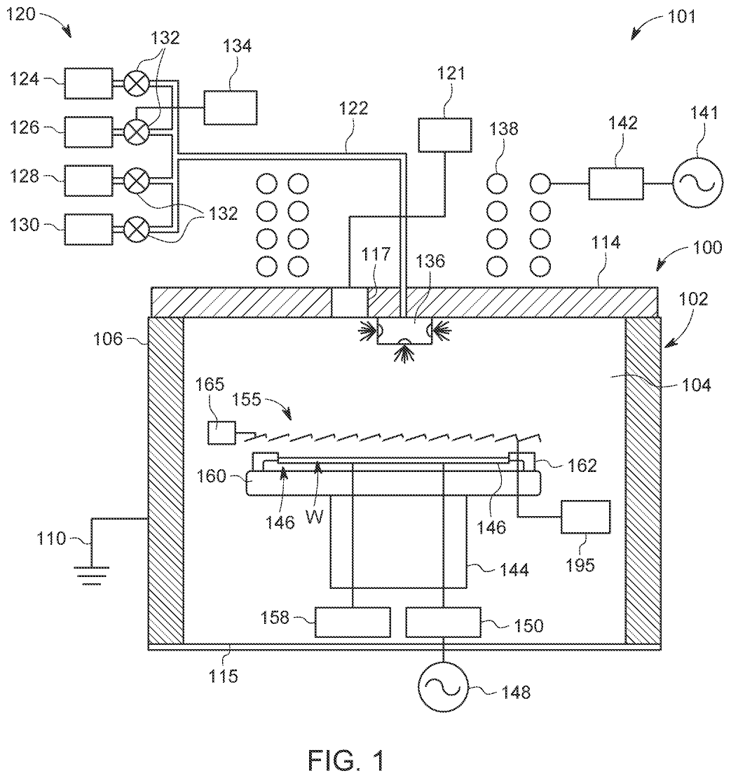

FIG. 1 is a schematic cross-sectional view of a processing apparatus 101 including an exemplary plasma processing chamber 100 suitable for performing a patterning process. One example of the plasma processing chamber 100 is a Sym3™ etching processing chamber, available from Applied Materials, Inc., located in Santa Clara, CA. It is contemplated that other process chambers, including those from other manufactures, may be adapted to practice embodiments of the disclosure.

The plasma processing chamber 100 includes a chamber body 102 having a chamber volume 104 defined therein. The chamber body 102 has sidewalls 106, a first end wall 114, and a second end wall 115, wherein any of the sidewalls 106, the first end wall 114, or the second end wall 115 may be coupled to ground 110. In some embodiments, the sidewalls 106 may have a liner to protect the sidewalls 106 and extend the time between maintenance cycles of the plasma processing chamber 100. The chamber body 102 may support the first end wall 114 and the second end wall 115, which enclose the chamber volume 104. The chamber body 102 may be fabricated from aluminum or other suitable materials. The dimensions of the chamber body 102 and related components of the plasma processing chamber 100 are not limited and generally are proportionally larger than the size of a substrate W to be processed therein. In various embodiments, the plasma processing chamber 100 may be cylindrical. Although non-limiting, examples of substrate sizes include 166 mm diameter, 250 mm diameter, 300 mm diameter and 450 mm diameter, among others.

In some embodiments, a pumping port (not shown) may be formed through the sidewall 106 of the chamber body 102 and connected to the chamber volume 104, while a pumping device (not shown) may be coupled through the pumping port to the chamber volume 104 to evacuate and control the pressure therein. The pumping device may include one or more pumps and throttle valves.

A gas panel 120 may be coupled by a gas line 122 to the chamber body 102 to supply process gases into the chamber volume 104. The gas panel 120 may include one or more process gas sources 124, 126, 128, 130 and may additionally include inert gases, non-reactive gases, and reactive gases, if desired. Examples of process gases that may be provided by the gas panel 120 include, but are not limited to, hydrocarbon containing gas including methane (CH₄), sulfur hexafluoride (SF₆), silicon chloride (SiCl₄), carbon tetrafluoride (CF₄), hydrogen bromide (HBr), hydrocarbon containing gas, argon gas (Ar), chlorine (Cl₂), nitrogen (N₂), helium (He) and oxygen gas (O₂). Additionally, process gases may include nitrogen, chlorine, fluorine, oxygen and hydrogen containing gases such as BCl₃, C₂F₄, C₄F₈, C₄F₆, CHF₃, CH₂F₂, CH₃F, NF₃, NH₃, CO₂, SO₂, CO, N₂, NO₂, N₂O, H₂, among others.

Valves 132 control the flow of the process gases from the process gas sources 124, 126, 128, 130 from the gas panel 120 and are managed by a controller 134. The flow of the gases supplied to the chamber body 102 from the gas panel 120 may include combinations of the gases.

The controller 134 may be utilized to control the process sequence, regulating the gas flows from the gas panel 120 into the plasma processing chamber 100 and other process parameters. Software routines, when executed by the controller 134, transform the controller 134 into a specific purpose computer (controller) that controls the plasma processing chamber 100 such that the processes are performed in accordance with the present disclosure. The software routines may also be stored and/or executed by a second controller (not shown) that is collocated with the plasma processing chamber 100.

The first end wall 114 may include a nozzle 136, wherein the nozzle 136 has one or more ports for introducing the process gases from the process sources 124, 126, 128, 130 of the gas panel 120 into the chamber volume 104. After the process gases are introduced into the plasma processing chamber 100, the gases are energized to form plasma. An antenna 138, such as one or more inductor coils, may be provided adjacent to the plasma processing chamber 100. An antenna power supply 141 may power the antenna 138 through a match circuit 142 to inductively couple energy, such as RF energy, to the process gas to maintain a plasma formed from the process gas in the chamber volume 104 of the plasma processing chamber 100. Alternatively, or in addition to the antenna power supply 141, process electrodes below the substrate W and/or above the substrate W may be used to capacitively couple RF power to the process gases to maintain the plasma within the chamber volume 104. The operation of the antenna power supply 141 may be controlled by a controller, such as controller 134, that also controls the operation of other components in the plasma processing chamber 100.

A platen or substrate support pedestal 144 to support the substrate W during processing is disposed within the chamber volume 104, above/adjacent the second end wall 115. The substrate support pedestal 144 may include an electrostatic chuck (ESC) 146 for holding the substrate W during processing, wherein the ESC 146 uses the electrostatic attraction to hold the substrate W to the substrate support pedestal 144. The ESC 146 may be powered by a pulsed DC power supply and/or an RF power supply 148 integrated with a match circuit 150. The ESC 146 may include an electrode embedded within a dielectric body. The electrode is coupled to the RF power supply 148 and provides a bias which attracts plasma ions, formed by the process gases in the chamber volume 104, to the ESC 146 and substrate W positioned thereon. The RF power supply 148 may cycle on and off, or pulse, during processing of the substrate W. In some embodiments, the ESC 146 may have an isolator (not shown) for the purpose of making the sidewall of the ESC 146 less attractive to the plasma to prolong the maintenance life cycle of the ESC 146.

In some embodiments, the electrode may be coupled to a power source 158. The power source 158 provides a chucking voltage of about 166 volts to about 1660 volts to the electrode. The power source 158 may also include a system controller for controlling the operation of the electrode by directing a DC current to the electrode for chucking and de-chucking the substrate W.

The ESC 146 may include one or more temperature controllers disposed therein and connected to a power source (not shown), for heating or cooling the substrate. For example, a cooling base 160 supporting the ESC 146 may include conduits for circulating a heat transfer fluid to maintain a temperature of the ESC 146 and substrate W disposed thereon. The ESC 146 is configured to perform in the temperature range required by the thermal budget of the device being fabricated on the substrate W. For example, the ESC 146 may be configured to maintain the substrate W at a temperature of about 25 degrees Celsius to about 500 degrees Celsius for certain embodiments.

A shield or cover ring 162 is disposed on the ESC 146 and along the periphery of the substrate support pedestal 144. The cover ring 162 is configured to confine etching gases to a desired portion of the exposed top surface of the substrate W, while shielding the top surface of the substrate support pedestal 144 from the plasma environment inside the plasma processing chamber 100. In some embodiments, the cover ring 162 may be powered by one or more power sources, such as the power source 158. Lift pins (not shown) may be selectively moved through the substrate support pedestal 144 to lift the substrate W above the substrate support pedestal 144 to facilitate access to the substrate W by a transfer robot (not shown) or other suitable transfer mechanism.

Adjacent the substrate W may be a plate assembly 155. As shown, the plate assembly 155 is positioned within the chamber volume 104. As will be described in greater detail herein, the plate assembly 155 may include optics having a plurality of areas to block ions and a plurality of apertures that allow for angled extraction of the ions, which are directed to the substrate W. The optics may be biased at a plate voltage, such as the extraction voltage or a different voltage through the use of a plate power source/supply 195. In some embodiments, this plate power supply 195 may be used to provide the extraction voltage to the plasma processing chamber 100. In other embodiments, the plate power supply 195 may only be in communication with the optics. Further, although one plate power supply 195 is illustrated, it is understood that multiple plate power supplies may be used in any embodiment. Still furthermore, the plate may be grounded while the substrate W is negatively biased. Thus, in certain embodiments, the plate voltage may be equal to the extraction voltage. In other embodiments, the plate voltage may be different than the extraction voltage. For example, in the case of a positive extraction voltage, the plate voltage may be less positive than the extraction voltage.

In some embodiments, the plate power supply 195 may be referenced to ground, the extraction voltage or to the substrate W. If referenced to the extraction voltage, the plate power supply 195 may supply a non-positive voltage, such as ground or a negative voltage. If the plate power supply 195 is referenced to the substrate W, the plate power supply 195 may supply a positive voltage. Embodiments are not limited in this context.

In some embodiments, chamber body 102 may further include a window 117 that facilitates optical process monitoring. Although shown as being formed within/through the first end wall 114, it will be appreciated that the window 117 may additionally or alternatively be formed through the second end wall 115 or the sidewalls 106. In one implementation, the window 117 is comprised of quartz or other suitable material that is transmissive to a signal utilized by an optical monitoring system 121 mounted outside the plasma processing chamber 100.

The optical monitoring system 121 is positioned to view at least one of the interior chamber volume 104 and/or the substrate W and the plate assembly 155. In one embodiment, the optical monitoring system 121 is coupled to the first end wall 114 and facilitates an integrated etch and/or deposition process that uses optical metrology to provide information that enables process adjustment to compensate for incoming substrate pattern feature inconsistencies (such as thickness, and the like), and provide process state monitoring (such as plasma monitoring, temperature monitoring, and the like) as needed. One optical monitoring system that may be adapted to benefit from the disclosure is the EyeD® full-spectrum, interferometric metrology module, available from Applied Materials, Inc., of Santa Clara, CA.

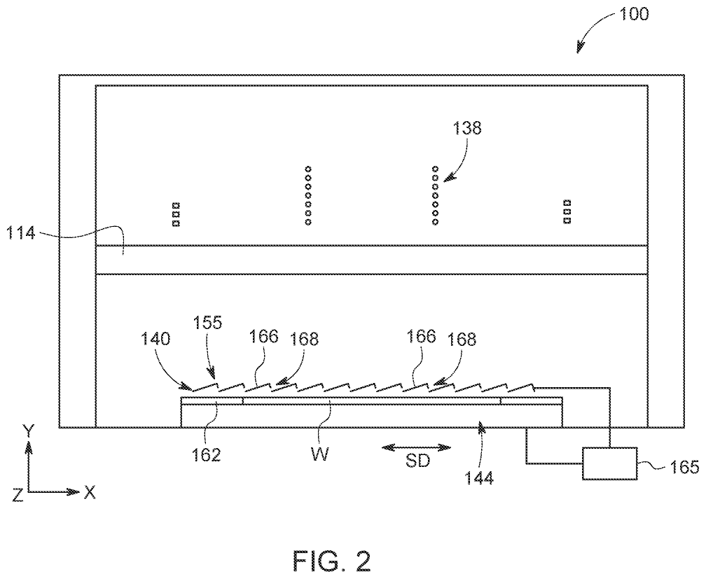

FIG. 2 shows an example of the plasma processing chamber 100 in greater detail. Only certain aspects of the chamber 100 are shown for ease of explanation. The plate assembly 155 includes a plate 140 proximate the substrate W, wherein the plate 140 includes a plurality of blocking portions 166 and apertures 168 that allow for angled extraction of an ion beam, which is directed to the substrate W. Although not limited to any particular number, the plate 140 may include thirteen (13) blocking portions 166, which together cover an approximately 300 mm wafer and part of the cover ring 162.

During processing of the substrate W, the plate 140 and/or the substrate support pedestal 144 may be moved or shifted relative to one another, e.g., in a shift direction ‘SD’, between a first position and a second position. In some embodiments, a distance between the first and second positions is a whole number of periods of the blocking portions 166 and/or the apertures 168 (“slit pitch”). As shown, the shift direction may be along the x-direction. In other embodiments, the shift direction may be along the z-direction. In still other embodiments, the shift direction may be along the x-z direction or the y-direction. Embodiments herein are not limited in this context.

The plate 140 and/or the ESC 146 may be moved using one or more electromechanical actuators 165. This dithering, or back and forth movement of the plate 140 and/or the substrate W, helps achieve a more uniform delivery of the ions to the substrate W during, for example, an etch process. As mentioned above, the substrate W and the ESC 146 may be subjected to a DC (pulsed DC) or RF biasing during the ion process. Meanwhile, biasing the plate 140 may adjust the ion angle between 25 to 65 degrees. Changing the z-gap (e.g., distance between plate 140 and the substrate W) may enable even lower ion delivery angles in some embodiments. Furthermore, it will be appreciated that the disclosure is not limited to the shown optics, but will work with optics of different shapes, sizes, materials, etc.

In other embodiments, dithering of the plate 140 and/or the substrate W helps achieve a more uniform delivery of the ions to the substrate W during a material deposition process. For example, a plasma deposition (PLAD) process may enable a liner to be formed, as desired, over the substrate W.

When the substrate W is being processed, the ion beam is scanned across the substrate W, between each side of the cover ring 162. When the ion beam reaches the end of a pass scan, e.g., the ion beam passes over an edge of the substrate W and is being directed into the cover ring 162, the ion beam turns around and begins passing in an opposite direction. In an ideal case, the ion beam is provided at a constant speed and infinite acceleration at the turnaround points, and the whole substrate W is be exposed to uniform ion flux each half cycle. However, in practice, the substrate W will slow down at the turnaround points, leading to higher local ion fluxes. To address this, the processing apparatus 101 of the present disclosure provides ramping acceleration with duty cycle correction. With more realistic wafer acceleration profiles at turnaround points, the ion flux non-uniformity can reach approximately 50%. It has been determined that scaling the duty cycle by the velocity profile restores uniform ion beam flux at the substrate W. To reduce loss in productivity, it's desirable to scan slower, spending less time near the turnaround points.

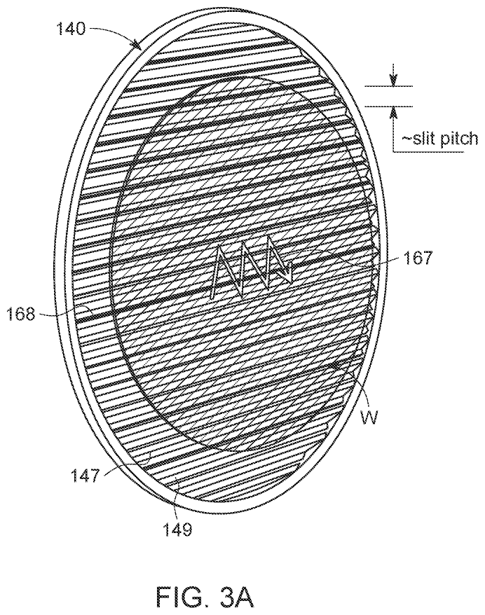

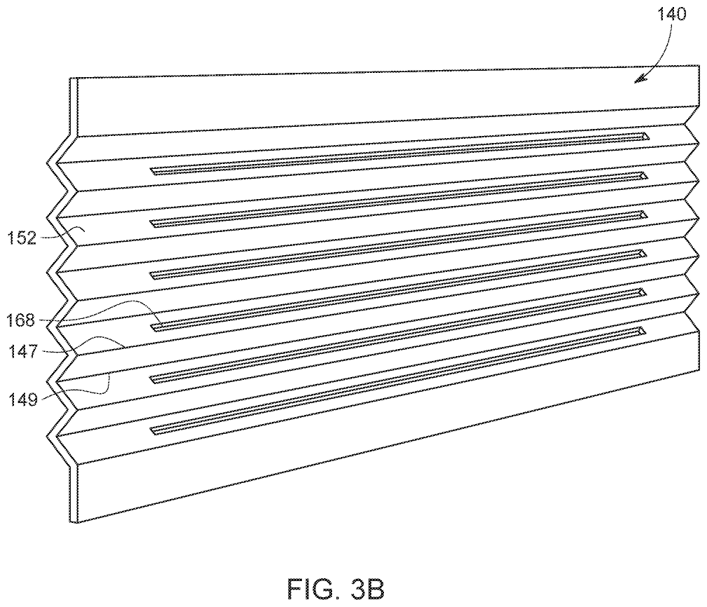

FIGS. 3A-3B further demonstrate the substrate W and the plate 140. In this non-limiting embodiment, the plate 140 has a series of parallel peaks 147 and valleys 149 arranged in an accordion configuration. Apertures 168 may be formed along one or more sidewalls 152, which connect the peaks 147 and valleys 149. Instead of using a small source or ribbon beam and scanning the wafer all the way through, as in some prior art approaches, embodiments herein allow for a large source together with a more limited dither scan. Advantageously, a smaller scan length can translate to a smaller process chamber, while the substrate W always being in the beam means higher throughput (e.g., up to 17× effective current) and a more uniform wafer temperature and pressure. Furthermore, a smaller halo leads to less foreign material sputtering. During use, the substrate W may be scanned over a horizontal and/or vertical range equal to the slit pitch times an integer. The substrate W then turns around and begins passing in an opposite direction, towards the second position.

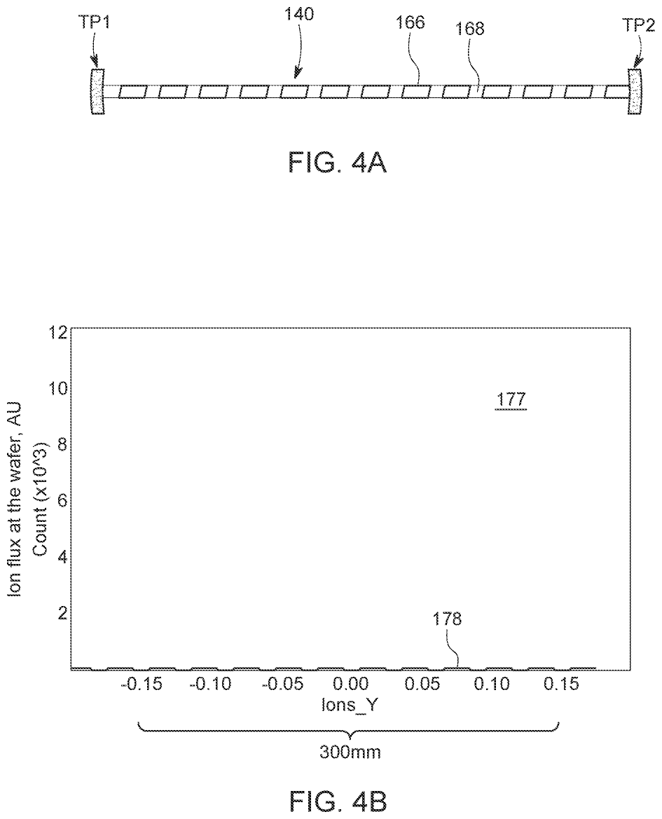

Processing of the substrate W between first and second turnaround points is further demonstrated in FIGS. 4A-8B, which show variation in the position and speed of the plate 140 relative to ion flux changes depending on plate positioning. Advantageously, scaling duty cycle by the velocity profile restores uniform ion beam flux at the wafer. More specifically, a power supply (e.g., the plate power supply 195, the power source 158, and/or the RF power supply 148) is operable to provide a pulsed bias signal to one or more of the substrate W, the shield ring 162, or the plate 140, wherein a duty cycle of the pulsed bias signal varies as the plate 140 is dithered relative to the substrate W. As a result, fewer ions are directed at the substrate W when the plate 140 is moving slower at the turnaround points, and the total ion dose is approximately equal for all times and positions of the moving plate.

FIG. 4A shows a side view of the plate 140 including the plurality of alternating blocking portions 166 and apertures 168 that allow for angled extraction of the ion beam, which is directed to the substrate W. FIG. 4B is a graph 177 demonstrating ion flux 178 of the ion beam at the substrate W. During use, the plate 140 is dithered back and forth between turnaround point 1 (‘TP1’) and turnaround point 2 (‘TP2’). In the example shown, the plate 140 is positioned at TP2 and speed of the substrate W is approximately zero, while the ion flux is substantially flat/uniform because the power supply has reduced the duty cycle. As a result, less ions are directed at the substrate W when the plate 140 is proximate TP2.

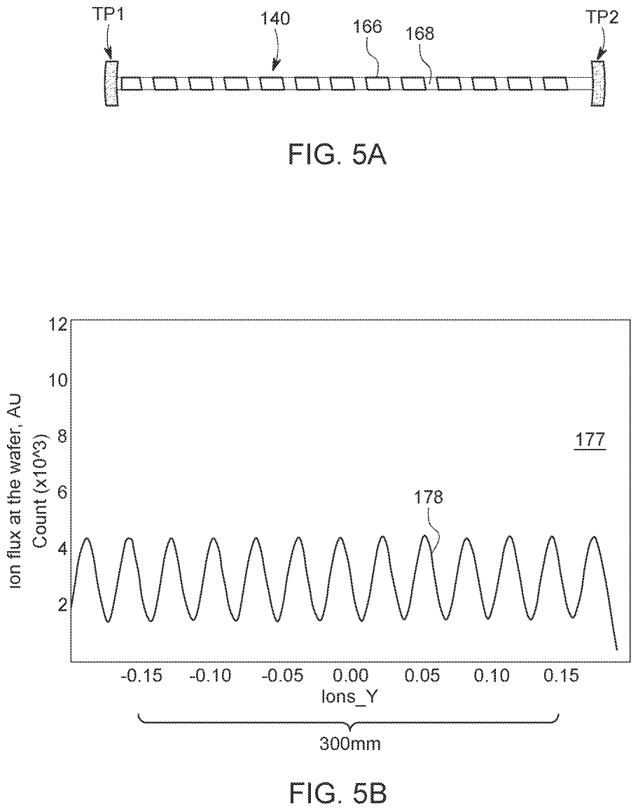

In FIGS. 5A-5B, the plate 140 is shown moving away from TP2 and towards TP1. With the plate 140 in this location and moving at maximum speed, the ion flux 178 of the ion beam at the substrate W begins to change/vary because the duty cycle of the bias signal is increased.

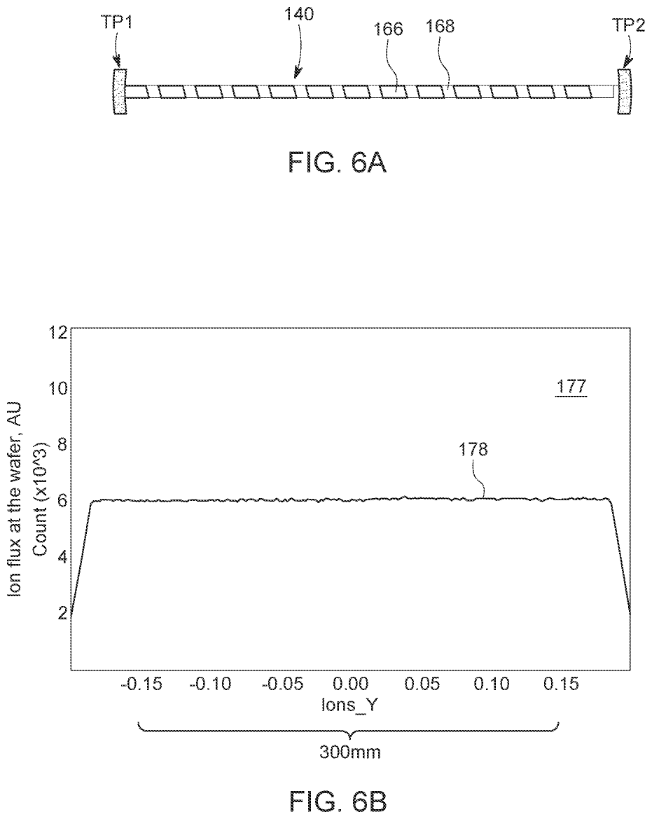

In FIGS. 6A-6B, the plate 140 is shown proximate TP1. When the plate 140 is positioned at TP1, the speed of the substrate W is again approximately zero and the ion flux is substantially flat/uniform because the duty cycle of the bias signal is decreased. As a result, less ions are directed at the substrate W when the plate 140 is proximate TP1.

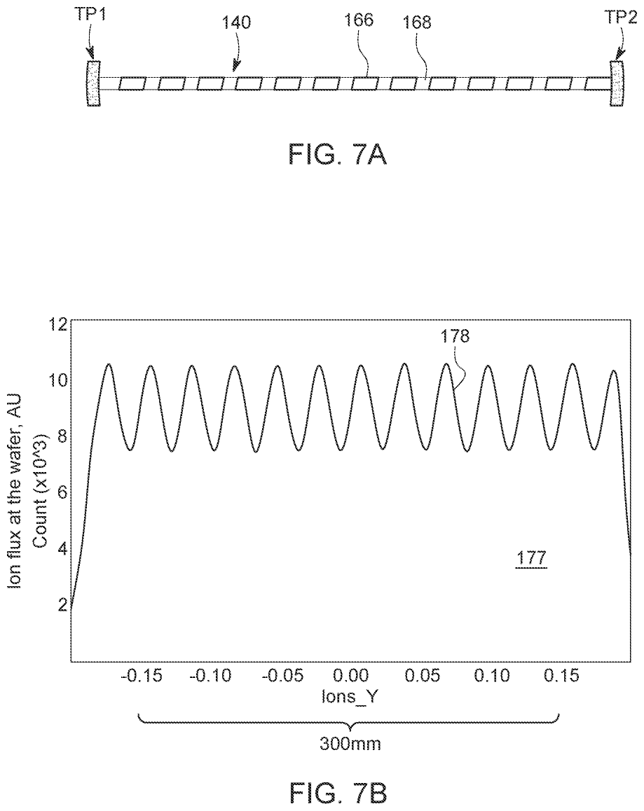

In FIGS. 7A-7B, the plate 140 is shown moving away from TP1 and towards TP2. With the plate 140 in this location and moving at maximum speed, the ion flux 178 of the ion beam at the substrate W again is variable/increased because the duty cycle of the bias signal is increased.

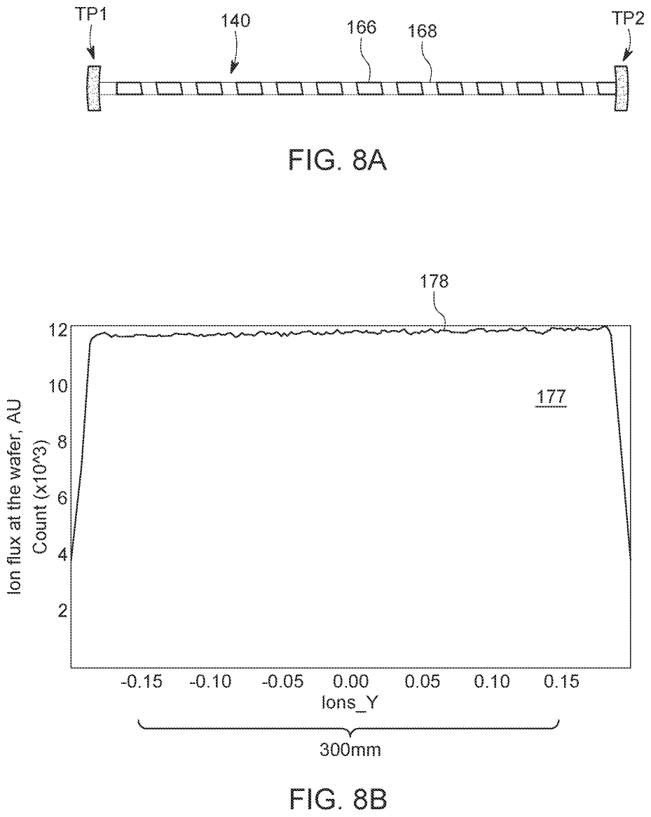

In FIGS. 8A-8B, the plate 140 has returned to TP1, and the ion flux is substantially flat/uniform because the duty cycle of the bias signal is decreased. As a result, less ions are directed at the substrate W when the plate 140 returns to TP1.

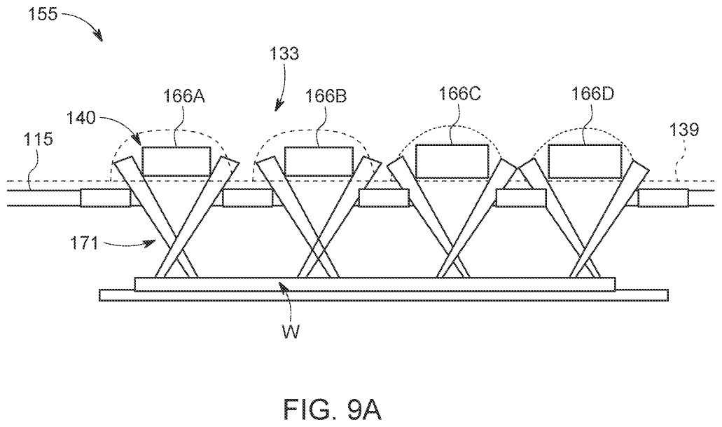

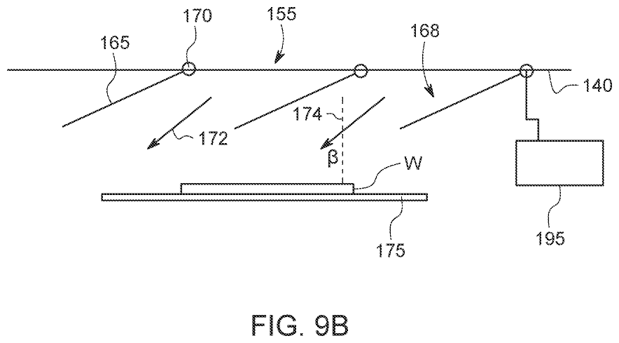

FIG. 9A represents one non-limiting embodiment of a portion of the ion extraction optics (hereinafter “optics”) 133 of the plate assembly 155. The optics 133 may be arranged along the second end wall 115, and may include the plate 140 having a plurality of blocking components/portions 166A-166D, arranged proximate apertures defined by the plate 140. As shown, the blocking portions 166A-166D define extraction slits, wherein these extraction slits may generate different ribbon beams or ion beamlets 171 that impact the substrate W. By selective arrangement of the blocking portions 166A-166D of the plate 140, mitigation of the difference in ion angular distributions of the ion beamlets extracted from the different extraction slits is possible. In an exemplary embodiment, the blocking portions 166A-166D and the extraction slits may be uniformly sized and spaced apart from one another. As a result, the different ribbon beams or ion beamlets 171 are uniform/symmetrical. It will be contemplated that the plate 140 may include additional blocking portions and therefore additional extraction slits and ribbon beams. For example, 15-20 blocking portions operable to cover a distance of approximately 350 mm may be employed in some embodiments. It will be further contemplated that the blocking portions of the plate 140 may be adjustable (e.g., rotatable) in alternative embodiments. Embodiments herein are not limited in this context, however.

FIG. 9B represents another non-limiting embodiment of the structure of the blocking portions and apertures disposed in the plate 140 of the plate assembly 155. In this embodiment, the plate 140 includes a plurality of rotatable components 166, which may be parallel and rotatable. These rotatable components 166 comprise a straight portion, similar to a slat or louver, and are rotatably attached to the plate 140, such as at proximal end 170. In other embodiments, the rotatable components 166 may be rotatably attached to the plate 140 at a different location, such as the midpoint of each plate 166.

Although non-limiting, each rotatable components 166 may be about 5 mm long, while the spacing between adjacent rotatable components 166 may also be about 5 mm. The openings between adjacent rotatable components 166 form apertures 168, through which ion beamlets 172 may be extracted. Each of the rotatable components 166 can rotate from a closed, or nearly closed, position where the rotatable components 166 is parallel or nearly parallel to the plate 140, to an open position where the rotatable components 166 is perpendicular to the plate 140. In the closed position, ions are not extracted from the plasma processing chamber, while in the open position, the ion beamlets 172 are extracted at an angle perpendicular to the substrate W. The angle in the closed position is referred to as 0°, while the angle in the open position is referred to as 90°. The rotatable components 166 may also assume any position between the open position and the closed position. In other words, as used herein, extraction angle refers to the angle formed between the plane parallel to the plate 140 and the rotatable components 166. Angle of incidence β refers to the angle formed between a parallel 174 extending from a top surface of the substrate W and the ion beamlets 172. The substrate W may be supported by a platen 175. In various embodiments, the plate 140 is biased at a plate voltage that is equal to the extraction voltage using the plate power supply 195.

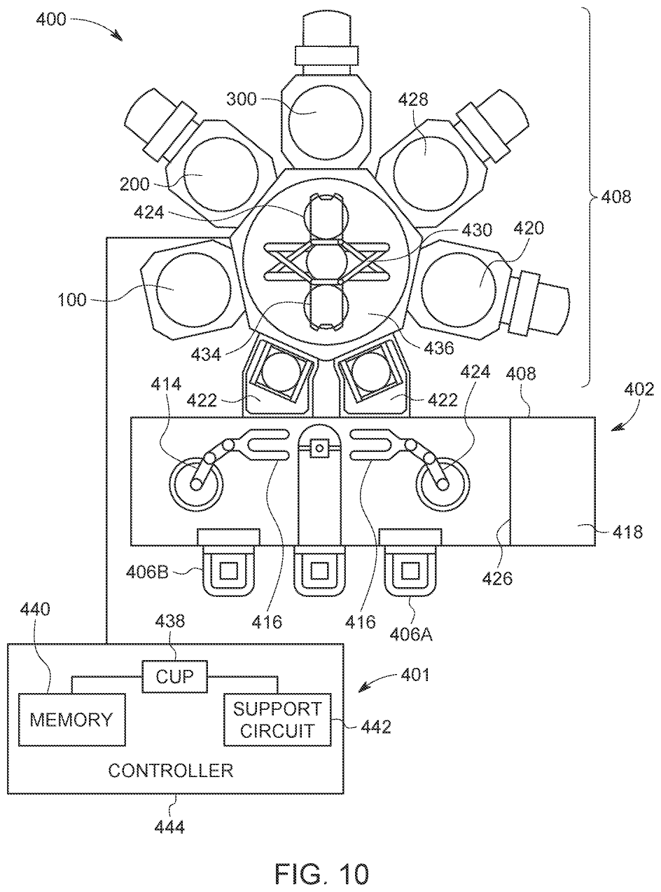

FIG. 10 is a schematic top plan view of an exemplary cluster processing system 400 that includes one or more of the processing chambers, such as the plasma processing chamber 100 described herein. In one embodiment, the cluster processing system 400 may be a CENTURA® or ENDURA® integrated processing system, commercially available from Applied Materials, Inc., located in Santa Clara, CA. It is contemplated that other processing systems (including those from other manufacturers) may be adapted to benefit from the disclosure.

The cluster processing system 400 may include a vacuum-tight processing platform 404, a factory interface 402, and a system controller 444. The platform 404 includes a plurality of processing chambers 100, 200, 300, 428, 420 and at least one load-lock chamber 422 that is coupled to a vacuum substrate transfer chamber 436. Two load lock chambers 422 are shown in FIG. 10. The factory interface 402 is coupled to the transfer chamber 436 by the load lock chambers 422.

In one embodiment, the factory interface 402 comprises at least one docking station 408 and at least one factory interface robot 414 to facilitate transfer of substrates. The docking station 408 is configured to accept one or more front opening unified pod (FOUP). Two FOUPS 406A-B are shown in the embodiment of FIG. 10. The factory interface robot 414 having a blade 416 disposed on one end of the robot 414 is configured to transfer the substrate from the factory interface 402 to the processing platform 404 for processing through the load lock chambers 422. Optionally, one or more metrology stations 418 may be connected to a terminal 426 of the factory interface 402 to facilitate measurement of the substrate from the FOUPS 406A-B.

Each of the load lock chambers 422 have a first port coupled to the factory interface 402 and a second port coupled to the transfer chamber 436. The load lock chambers 422 are coupled to a pressure control system (not shown) which pumps down and vents the load lock chambers 422 to facilitate passing the substrate between the vacuum environment of the transfer chamber 436 and the substantially ambient (e.g., atmospheric) environment of the factory interface 402.

The transfer chamber 436 has a vacuum robot 430 disposed therein. The vacuum robot 430 has a blade 434 capable of transferring substrates 424 among the load lock chambers 422, the metrology system 410 and the processing chambers 100, 200, 332, 428, 420.

In one embodiment of the cluster processing system 400, the cluster processing system 400 may include one or more processing chambers 100, 200, 300, 428, 420, which may be a deposition chamber (e.g., physical vapor deposition chamber, chemical vapor deposition, or other deposition chambers), annealing chamber (e.g., high pressure annealing chamber, RTP chamber, laser anneal chamber), etch chamber, cleaning chamber, curing chamber, lithographic exposure chamber, or other similar type of semiconductor processing chambers.

The system controller 444 is coupled to the cluster processing system 400. The system controller 444, which may include the computing device 401 or be included within the computing device 401, controls the operation of the cluster processing system 300 using a direct control of the processing chambers 100, 200, 300, 428, 420 of the cluster processing system 400. Alternatively, the system controller 444 may control the computers (or controllers) associated with the processing chambers 100, 200, 300, 428, 420 and the cluster processing system 400. In operation, the system controller 444 also enables data collection and feedback from the respective chambers to optimize performance of the cluster processing system 400.

The system controller 444, much like the computing device 401 described above, generally includes a central processing unit (CPU) 438, a memory 440, and support circuits 442. The CPU 438 may be one of any form of a general-purpose computer processor that can be used in an industrial setting. The support circuits 442 are conventionally coupled to the CPU 438 and may comprise cache, clock circuits, input/output subsystems, power supplies, and the like. The software routines transform the CPU 438 into a specific purpose computer (controller) 444. The software routines may also be stored and/or executed by a second controller (not shown) that is located remotely from the cluster processing system 400.

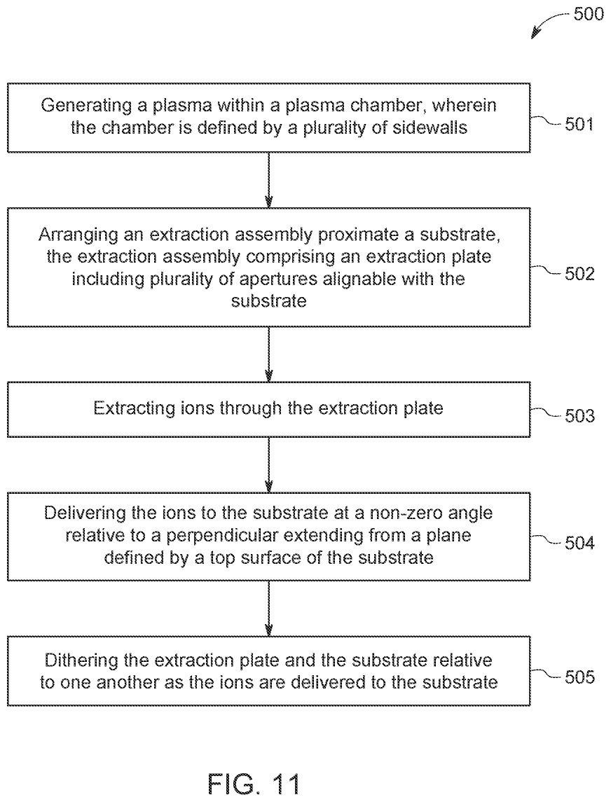

FIG. 11 depicts a flow diagram illustrating a process 500 for high throughput angled ion processing according to embodiments of the present disclosure. At block 501, the process 500 may include generating a plasma within a plasma chamber, wherein the chamber is defined by a plurality of sidewalls. In some non-limiting embodiments, the plasma processing chamber includes a chamber body having a chamber volume defined therein. The chamber body has sidewalls and a bottom, which may be coupled to ground. The sidewalls may have a liner to protect the sidewalls.

In some embodiments, generating the plasma may include energizing a process gas to form the plasma in the chamber using an RF coil, wherein the RF coil is positioned adjacent the plurality of sidewalls of the plasma chamber.

At block 502, the process 500 may include arranging a plate assembly proximate (e.g., above) a substrate, the plate assembly comprising a plate defining a plurality of apertures. In some embodiments, the plate may include a plurality of blocking portions adjacent the plurality of apertures. In some embodiments, the plate may include a cut-out region, and at least one rotatable blocking portion disposed over the cutout region. The blocking portion(s) may define one or more extraction slits for ions to pass therethrough.

At block 503, the process 500 may include extracting ions through the plurality of apertures. In some embodiments, the blocking portions generate different ribbon beams or ion beamlets that impact the substrate W. By selective arrangement of the blocking portions, mitigation of the difference in ion angular distributions of the ion beamlets extracted from the different extraction slits is possible. In some embodiments, the blocking portions and the extraction slits may be uniformly sized and spaced apart from one another.

At block 504, the process 500 may include delivering the ions to a substrate at a non-zero angle relative to a perpendicular extending from a plane defined by a top surface of the substrate. In some embodiments, the ions are delivered to the substrate to etch one or more areas of the substrate, and/or to etch one or more layers or features formed atop the substrate. In other embodiments, ions are delivered to the substrate to deposit a material atop the substrate (e.g., a liner layer, hardmask layer, etc.). During processing, the substrate W remains generally aligned with the plate throughout an entirety of the scan cycle. Said another way, a perimeter of the substrate W remains within a projection of a perimeter of the plate throughout the scan cycle. As a result, no large area for overscanning adjacent the substrate is needed.

At block 505, the process 500 may include moving the plate and the substrate relative to one another as the ions are delivered to the substrate. In some embodiments, an actuator may be used to dither the plate and the substrate relative to one another, between a first position and a second position, as the ions are extracted through the opening. The plate and/or the substrate may be dithered back and forth along a first direction, which is substantially parallel to a plane defined by the top surface of the substrate. In other embodiments, the plate and/or the substrate may be dithered back and forth along a second direction, which is substantially parallel to the plane defined by the top surface of the substrate, and which is substantially perpendicular to the first direction. In some embodiments, the plate is movable while the substrate is stationary. In other embodiments, the substrate is movable and the plate is stationary. In still other embodiments, the plasma source may be pulsed or dithered while the plate and/or the substrate are stationary. In some embodiments, the substrate is DC (e.g., pulsed DC) or RF biased as the ions are delivered to the substrate.

In some embodiments, a duty cycle is varied as the substrate or plate are being dithered, wherein the duty cycle may be varied by varying the pulsed bias signal to one or more of the following: the substrate, a shield ring adjacent the substrate, and the plate. In some embodiments, the power supply reduces the duty cycle when the substrate is in the first position and/or the second position, wherein the first and second position represent turnaround points of the substrate. As the substrate moves between the first and second positions, the duty cycle may be increased. Reducing and increasing the duty cycle based on a location of the plate provides a substantially uniform ion dose of the ions delivered to the substrate. As a result, ion etching and/or material deposition is more uniform.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A processing apparatus, comprising:
a chamber operable to contain a plasma within a chamber volume, the chamber defined by a plurality of sidewalls;
a plate assembly proximate a substrate, the plate assembly comprising a plate defining a plurality of apertures, wherein ions are extracted through the plurality of apertures and are delivered to the substrate at a non-zero angle relative to a perpendicular extending from the substrate; and
an actuator operable to dither the plate and the substrate relative to one another as the ions are extracted through the plurality of apertures.

2. The processing apparatus of claim 1, wherein the plate further comprising a plurality of blocking portions to block the ions, and wherein ion beamlets are extracted through the plurality of apertures.

3. The processing apparatus of claim 2, wherein each of the plurality of blocking portions comprises a straight portion.

4. The processing apparatus of claim 2, wherein the plate comprises a series of peaks and valleys, and wherein a first aperture of the plurality of apertures is located between a first peak and a first valley of the series of peaks and valleys.

5. The processing apparatus of claim 1, further comprising a power supply operable to provide a pulsed bias signal to one or more of the following: the substrate, a shield ring adjacent the substrate, and the plate, wherein a duty cycle of the pulsed bias signal varies as the plate is dithered relative to the substrate as the ions are extracted through the plurality of apertures.

6. The processing apparatus of claim 5, wherein the actuator is operable to dither the plate repeatedly between a first position and a second position while the substrate remains in a stationary position, and wherein the power supply reduces the duty cycle when the plate is in the first position and the second position.

7. The processing apparatus of claim 6, wherein the power supply increases the duty cycle when the plate is moving between the first position and the second position.

8. The processing apparatus of claim 1, wherein the plate assembly is located within the plasma chamber.

9. A plasma processing apparatus, comprising:
a plasma chamber operable to contain a plasma within a chamber volume, the plasma chamber defined by a plurality of sidewalls;
a plate assembly within the plasma chamber, wherein the plate assembly is arranged above a substrate, wherein the plate assembly comprises a plate defining a plurality of apertures, and wherein ions are extracted through the plurality of apertures and delivered to the substrate at a non-zero angle relative to a perpendicular extending from the substrate; and
an actuator operable to dither the plate and the substrate relative to one another as the ions are extracted through the plurality of apertures.

10. The plasma processing apparatus of claim 9, wherein the plate further comprising a plurality of blocking portions to block the ions, and wherein ion beamlets are extracted through the plurality of apertures.

11. The processing apparatus of claim 9, further comprising a power supply operable to provide a pulsed bias signal to the substrate or to a shield ring adjacent the substrate, wherein a duty cycle of the pulsed bias signal varies as the plate is dithered relative to the substrate as the ions are extracted through the plurality of apertures.

12. The processing apparatus of claim 11, wherein the actuator is operable to dither the plate repeatedly between a first position and a second position while the substrate remains in a stationary position, and wherein the power supply reduces the duty cycle when the plate is in the first position and the second position.

13. The processing apparatus of claim 12, wherein the power supply increases the duty cycle when the plate is moving between the first position and the second position.

14. The plasma processing apparatus of claim 9, wherein the plate comprises a series of peaks and valleys, wherein a first aperture of the plurality of apertures is located between a first peak and a first valley of the series of peaks and valleys, and wherein the first peak and the first valley are directly adjacent one another.

15. A method, comprising:
generating a plasma within a chamber volume of a plasma chamber, wherein the plasma chamber is defined by a plurality of sidewalls;
arranging a plate assembly above a substrate, the plate assembly comprising a plate defining a plurality of apertures;
extracting ions through the plurality of apertures;
delivering the ions to the substrate at a non-zero angle relative to a perpendicular extending from a plane defined by a top surface of the substrate; and
dithering the plate and the substrate relative to one another as the ions are extracted through the plurality of apertures and delivered to the substrate.

16. The method of claim 15, wherein dithering the plate and the substrate relative to one another comprises moving the plate while the substrate is stationary.

17. The method of claim 15, wherein dithering the plate and the substrate relative to one another comprises moving the substrate while the plate is stationary.

18. The method of claim 15, further comprising providing a pulsed bias signal from a power supply to the substrate or to a shield ring adjacent the substrate, wherein a duty cycle of the pulsed bias signal varies as the plate and the substrate are dithered relative to one another.

19. The method of claim 18, further comprising:
repeatedly dithering the plate relative to the substrate, between a first position and a second position; and
reducing the duty cycle when the plate is in the first position and the second position, and increasing the duty cycle when the plate is moving between the first position and the second position, wherein reducing and increasing the duty cycle based on a location of the plate provides a substantially uniform ion dose of the ions delivered to the substrate.

20. The method of claim 15, wherein delivering the ions to the substrate comprises delivering the ions to the substrate as part of an etching process or as part of a material deposition process.
